(19) United States
(12) Patent Application Publication
(10) Pub. No.: US 2013/0294075 A1
(43) Pub. Date: Nov. 7, 2013

(54) Lighting system and method of manufacture

(71) Applicants: Hugo Johan Cornelissen, Waalre (NL); Giovanni Cennini, Eindhoven (NL); Tim Dekker, Eindhoven (NL)

(72) Inventors: Hugo Johan Cornelissen, Waalre (NL); Giovanni Cennini, Eindhoven (NL); Tim Dekker, Eindhoven (NL)

(73) Assignee: Koninklijke Phillips Electronics N.V., Eindhoven (NL)

(21) Appl. No.: 13/995,996

(22) PCT Filed: Dec. 9, 2011
(86) PCT No.: PCT/IB11/55563

§ 371 Date: Jun. 20, 2013

(30) Foreign Application Priority Data
Dec. 21, 2010 (EP) 10196085.4

(51) Int. Cl. F21V 7/00; H05K 3/10

(52) U.S. Cl. CPC F21V 7/0083; H05K 3/10
USPC 362/235; 29/846

(57) ABSTRACT

A lighting system comprises a circuit board (30) which carries a lighting circuit comprising a plurality of lighting elements (72). The surface of the circuit board (30) carrying the lighting elements is at least partially reflective. A spacer layer (70) is over the circuit board and a top reflector (82) is over the spacer layer. The spacer layer defines a light cavity air gap between the circuit board and the top reflector, and the top reflector and/or the circuit board is provided with an array of light out-coupling structures.

### FIELD OF THE INVENTION

The present invention relates to a lighting system, in particular in the form of a light emitting sheet, for example using LED light sources. It also relates to a method of manufacture.

### BACKGROUND OF THE INVENTION

Lighting systems utilizing light emitting diodes (LEDs) as their light sources have become increasingly popular. Such light output devices can be used for illumination of objects, for display of an image, or simply for decorative purposes.

LEDs are made by connecting the n-type semiconductor region and the p-type semiconductor region of an LED chip to respective terminal pins for drawing electric current. The LED chip is embedded in a package, for example of a resin. The package may be arranged so that light from the LED chip is emitted in one or more designated directions.

LEDs have a small form factor, which enables thin and versatile designs to be formed. One example is a light emitting sheet which can be placed over, or integrated with a surface. A light emitting sheet is for example provided with an embedded LED or an array of embedded LEDs. The LEDs emit light at their locations within the sheet.

The small form factor of the LEDs translates to very high brightness, for example exceeding 10⁶ cd/m².

Thus, a problem with light emitting sheets with integrated arrays of LEDs is that the sheet has local high intensity regions at the LEDs. The individual LEDs can create glare as well as unwanted shadowing effects. In many applications, it is desired to obtain a more uniform light output intensity across the area of the sheet, for example spreading the LED light output over a larger area of for example 1 to 10 cm². Secondary optics, such as light diffusing layers or scattering surfaces can be used for this purpose.

Another example of a light emitting sheet uses a light cavity to spread light and thereby generate a more uniform output. Light cavities are for example used in backlight units for LCDs, where the uniformity of the output is of particular importance. Such a cavity can be in the form of a foil, which is illuminated by edge-mounted LEDs.

One example of this type of foil is a PMMA (Poly(methyl methacrylate)—a transparent thermoplastic) waveguide, sometimes known as a light skin. Light is captured within the waveguide by total internal reflection, and light out-coupling structures are used to generate the uniform illumination at the light output surface. These light out-coupling structures provide a change in refractive index or a change in the angle of the light, such as to interrupt the total internal reflection. For example they can comprise light scattering regions. The out-coupling areas are arranged with reference to the LED positions—for example closer together further away from the LEDs, because the intensity is lower, so that more light output areas are needed for a uniform intensity over the area of the light output surface.

FIG. 1 shows a PMMA waveguide light emitting sheet, and shows edge coupled LEDs 10 (for example red, green and blue), the waveguide 12 and the irregular pattern of light out-coupling structures 14. The pattern is calculated precisely to ensure a good uniformity. The waveguide is for example 1 mm thick.

FIG. 2 shows the structure of FIG. 1 in cross section.

The light out-coupling structure can take various forms, such as scattering paint dots, micro-grooves, micro-prisms, microlenses, domains with surface roughness, phosphor dots. The waveguide is usually produced by injection moulding.

The PMMA (or other plastic material transparent to light, such as polycarbonate) is injected into metal moulds with carefully polished or micro-structured walls and inserts. After injection at high pressure and temperature, the plastic cools down and solidifies.

While PMMA can be used as light guides in backlighting, the requirements on fire safety do not allow for PMMA in general illumination. For this reason, PMMA is mainly used in closed systems.

Polycarbonate (PC) can also be used. PC is more fire resistant and can be used in lighting. However, because of its high absorption properties it is not a preferred material in realizing large area lighting.

Also, both of these a moulded plastic light guide solutions adds considerable weight to the whole luminaire.

There is therefore a need for a fire safe, light-weight way to obtain uniform light distribution.

### SUMMARY OF THE INVENTION

According to the invention, there is provided a lighting system comprising:

a circuit board which carries a lighting circuit comprising a plurality of lighting elements, wherein the surface of the circuit board carrying the lighting elements is at least partially reflective;

a spacer layer over the circuit board;

a top reflector over the spacer layer, wherein the spacer layer defines an air gap between the circuit board and the top reflector,

wherein the top reflector and/or the circuit board is provided with a light out-coupling structure,
and wherein the circuit board comprises a patterned top conductor which has an array of isolated conductor areas surrounded by a common conductor area, wherein one or more lighting elements are connected between each isolated conductor area and the common conductor area.

This structure uses a spacer layer to define an air cavity between reflecting layers, such as foils. The lighting elements are distributed across the area of the light output surface of the lighting system, which facilitates the generation of a uniform light output. A parallel connection of the lighting elements is provided so that the lighting system can be cut to size. This is possible since the remaining connections after cutting are still functional. The remaining isolated areas can be used, and the remaining part of the common conductor area still remains electrically intact.

It also enables the system to be compact, in that no edge mounted light source is required.

The structure is simple to manufacture, for example with printing of the spacer layer over a printed circuit board, followed by mounting of the top reflector.

The circuit board, spacer and top reflector can be made from any suitable materials. In particular optical transparency is not important, so that the cavity can be made from materials which meet fire safety requirements. This is an advantage over existing PMMA-based light guides.

Compared to solid light guide designs (such as PC and PMMA), there is a reduced use of material and weight.

The surface of the circuit board carrying the lighting elements can be provided with a reflective foil. This provides the desired reflectivity of the circuit board (such as a PCB). Alternatively, the surface of the circuit board carrying the lighting elements has a paint coating. This is likely to be less reflective but is simpler to apply.

The spacer layer defines a grid, with the same number of one or more lighting elements in each grid opening. Each grid opening then defines a light source area, and the grid preferably repeats over the whole area of the lighting system so that a uniform light output is obtained.

The spacer layer can be formed of a partially transparent material, so that there is mixing between grid openings. However, the spacer layer can be reflective, absorptive or light scattering.

The array of light out-coupling structures can comprise an array of holes. These can be in a regular pattern so that the hole arrangement is the same for each grid opening.

The circuit board can comprise a bottom conductor on the opposite side of the board, and wherein the system comprises an ac power supply connected between the common conductor area and the bottom conductor.

The lighting elements can comprise LEDs, for example side emitting LEDs.

The invention also provides a method of manufacturing a lighting system, comprising:

providing a circuit board which carries a lighting circuit comprising a plurality of lighting elements, wherein the surface of the circuit board carrying the lighting elements is at least partially reflective;

providing a spacer layer over the circuit board; and

providing a top reflector over the spacer layer, wherein the spacer layer defines an air gap between the circuit board and the top reflector; wherein the top reflector and/or the circuit board is provided with an array of light out-coupling structures.

The spacer layer can be formed by printing.

### BRIEF DESCRIPTION OF THE DRAWINGS

Examples of the invention will now be described in detail with reference to the accompanying drawings, in which:

FIG. 1 shows a known light emitting sheet in perspective view;

FIG. 2 shows the light emitting sheet of FIG. 1 in cross section;

FIG. 3 shows the design of printed circuit board used in the system of the invention, and which functions as one reflector of the cavity;

FIG. 4 shows how the lighting elements are connected to the printed circuit board of FIG. 3;

FIG. 5 shows the circuit connection of the lighting elements;

FIG. 6 shows the electrical connections for multiple lighting elements;

FIG. 7 shows two possible designs of spacer layer and lighting element positioning; and

FIG. 8 shows three possible cavity designs in cross section.

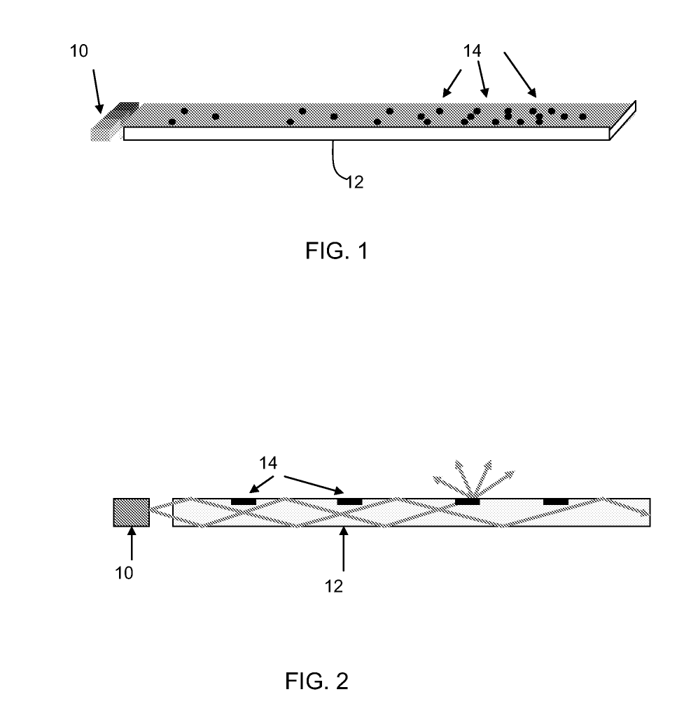

### DETAILED DESCRIPTION OF THE EMBODIMENTS

The invention provides a lighting system having a light guide comprising an air cavity realized by two reflective surfaces that can spread and extract light of LEDs. The surfaces can be formed as foils, which are spaced by a spacer layer preferably of flexible material, and which defines a grid.

Preferred examples of the system of the invention have a printed circuit board which carries the lighting elements, such as LEDs. This board is made reflective so that it functions as one reflector of a cavity. Another reflector is provided over the printed circuit board, with a spacing defined by a spacer layer.

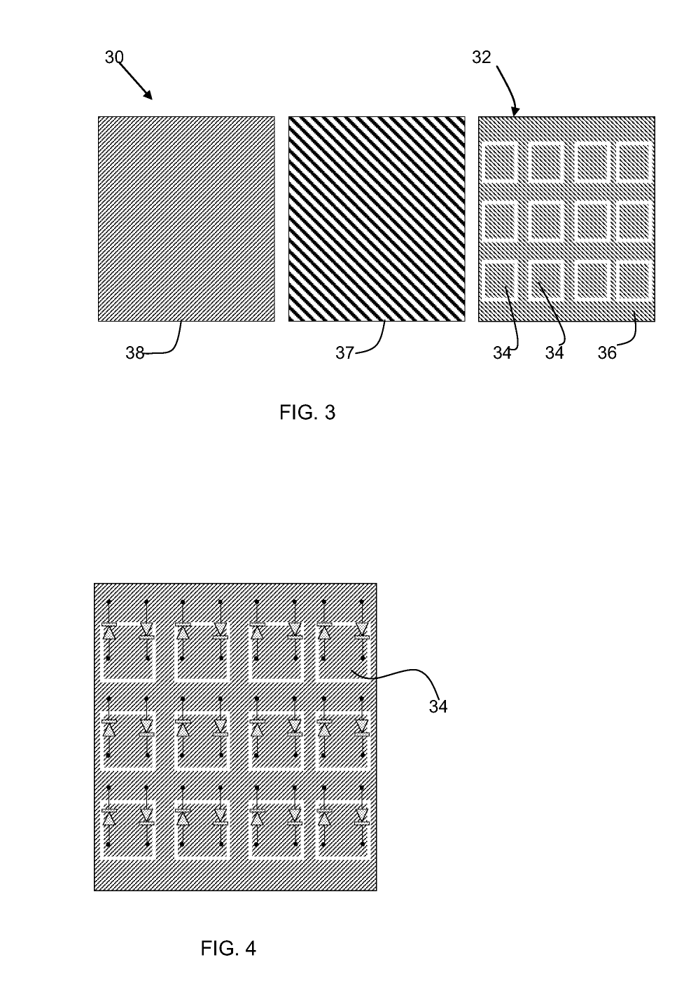

FIG. 3 shows the design of printed circuit board 30 used in the system of the invention, and which functions as one reflector of the cavity.

The circuit board 30 comprises a patterned top conductor 32 which has an array of isolated conductor areas 34 surrounded by a common conductor area 36. A separation gap around the conductor areas 34 is formed by the patterns which are printed to isolate them.

The isolated areas preferably define a regular grid of spaced areas, arranged in rows and columns. The common conductor area is thus defined as continuous sheet with an grid of openings in which the isolated areas are formed.

The top conductor is provided over a dielectric layer 37, and there is a bottom conductor 38. Thus, the three patterns shown in FIG. 3 are stacked to define the printed circuit board 30.

All of the areas 34 are floating and not connected to the power supply. The connection to the power supply is made on the common conductor area 36 of the top electrode 32 and bottom conductor 38 (FIG. 3,5). The dielectric layer 37 comprises a conventional circuit board laminate.

The circuit board 30 can be flexible, and the three layers 36,37,38 can for example comprise two copper conductor layers deposited on both sides of a polyimide dielectric.

FIG. 4 shows how the lighting elements are connected to the printed circuit board of FIG. 3. Each conductor area 34 is connected to the anode of one LED and the cathode of another LED. The two LEDs are in anti-parallel between the conductor area 34 and 36.

This means there is illumination in both phases of an ac drive signal.

All of the LED-pairs are mounted in parallel, and this gives a cut-to-measure functionality of the lighting system, in that any number of LEDs can be removed without needing to change the drive connections to the others, and without changing the brightness of the remaining LEDs. This is however only one of many possible connection schemes.

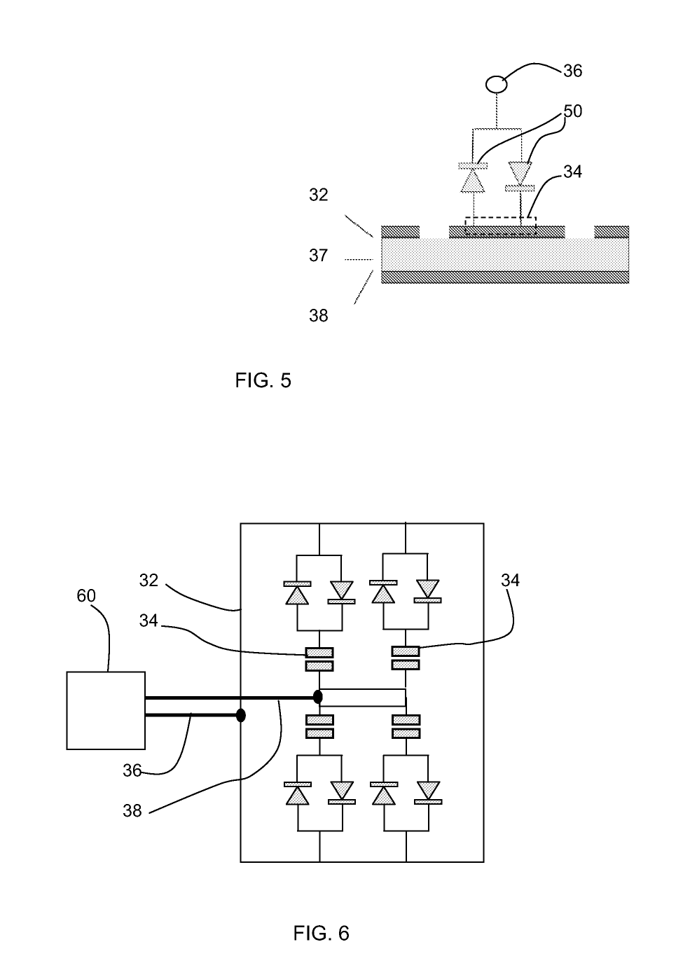

FIG. 5 shows the circuit board 30 in cross section, and shows a single pair of anti-parallel diodes 50 making electrical connection to the top conductor layer 34. The top terminal connects to the common conductor area 36, and the bottom terminals connect to the isolated area 34.

FIG. 6 shows the power supply 60 that applies a voltage between the bottom electrode 38 and the connected part of the top electrode 32. The load driven by the power supply thus comprises the anti-parallel diode pairs and a capacitance associated with each diode pair. At the driving frequency, the capacitance (through the circuit board) does not hinder correct operation of the circuit.

The LEDs are surface mounted devices, e.g. side-emitting LEDs, soldered to the flexible PCB. After soldering of the LEDs a flexible spacer grid is printed/manufactured with a 3D printing/manufacturing technique.

The grid serves as spacer and defines an array of optical cells. The light from one LED or a set of LEDs can be contained within a grid, or else the light from LEDs in different grid cells can be allowed to mix.

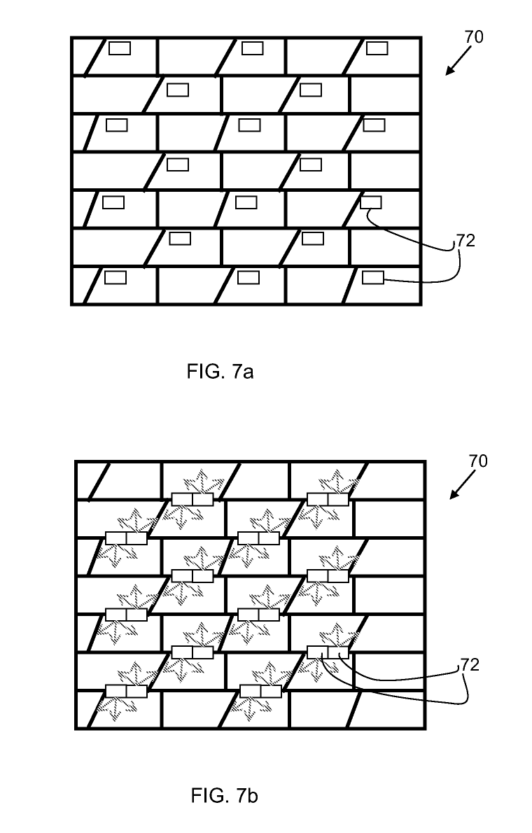

FIGS. 7a and 7b shows examples of the spacer grid 70. Essentially, a regular rectangular array of grid walls defines a set of grid openings. The LED or LEDs of a grid opening are within the spacer walls in the example of FIG. 7a, for example LED set 72. In the example of FIG. 7b, and LED package 72 is on the boundary between grid openings, so that one LED output is directed into one grid opening and another LED output is directed to an opposite grid opening.

The grid needs to be able to maintain a constant spacing, and it may therefore have a more dense grid pattern than the required density of LEDs. This is shown in FIG. 7a, where an LED set is provided only every other grid opening. Of course, there may be an LED set in each grid opening.

The grid can be essentially rectangular, as shown, or it may be a hexagonal grid, or indeed any other pattern.

The shape of the grid pattern is selected taking into account the illumination pattern of the LEDs. Thus, as schematically shown in FIGS. 7a and 7b, the grid openings may not be regular polygons, but may have staggered side walls designed taking into account the LED output, for example of side emitting LEDs.

The grid is formed from materials as used in 3D-printing/rapid-prototyping techniques. Common techniques are stereo lithography, where photo-polymers like acrylates, epoxy resins and acrylonitrile butadiene styrene (ABS) plastic are used, or Selective Laser Sintering SLS which uses materials such as nylon, polystyrene, fine Alumide.

The dimensions of the grid openings may typically be in the range 10 mm to 100 mm. The grid thickness is approximately 0.5 mm to 5 mm, for example approximately 1 mm.

A top reflector is provided over the spacer layer. The air gap defined by the spacer layer defines an optical cavity within which the light emitted by the LED is contained until it reaches an out-coupling structure, which allows the light to leave the cavity.

In the simplest form, the light out-coupling structure comprises openings which allow the escape of light. These can be formed in the bottom circuit board, or in the top reflector, or in both if illumination from both faces is desired.

The light out-coupling can also be achieved by using a partially transmissive material, for example a partially reflective and partially transmissive material at the top of the cavity.

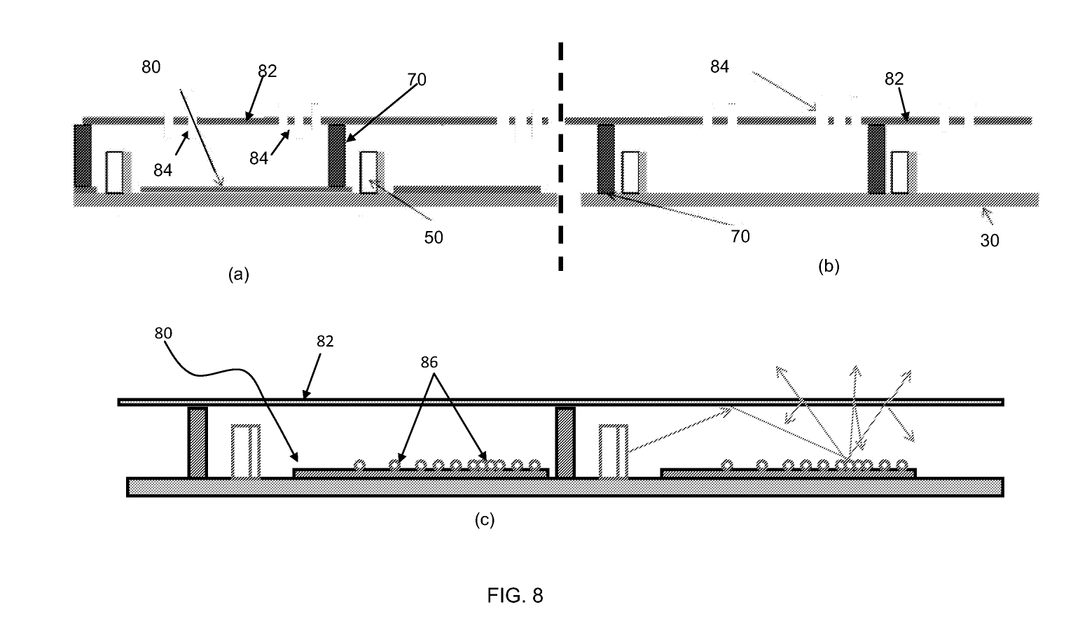

FIG. 8 shows three possible cavity designs in cross section.

FIG. 8(a) shows a design which uses two reflecting foils, one 80 attached to the PCB between the mounted LEDs 50 and the other 82 on top of the spacer grid 70.

The top reflector foil 82 is provided with apertures 84 which allow for extraction of light that propagates inside the air cavity. These apertures can be uniformly distributed across the top reflector foil, or they can have a pattern which is designed to provide uniform output illumination (i.e. uniform light output intensity per unit area) across the area of the grid cell within which the LED 50 (or LED set) is positioned.

FIG. 8(b) shows a design which uses only a top reflecting foil 82. The lower surface of the air-cavity is formed by the PCB itself 30, which is painted white, or painted with another reflective coating. The light out-out-coupling structures again comprise apertures 84 in the top reflector.

FIG. 8(c) shows a design which uses a partially-transparent top foil 82 in combination with a bottom foil 80 that has a scattering pattern 86. The pattern 86 is designed to achieve uniform light out-coupling in combination with the partially transmissive top foil. The light out-coupling structure can take other forms as known in the prior art, such as scattering paint dots, micro-grooves, micro-prisms, microlenses, domains with surface roughness, phosphor dots.

In the examples of FIG. 8, light is extracted from one side only. However, it is straightforward to realize an air cavity with double extractions at both sides.

Thus, the basic structure of the lighting system of the invention comprises a PCB foil, which may be flexible, a spacer grid, with LEDs within the grid, and which also may be flexible. A top reflecting foil completes the reflective cavity.

The grid can be made from flexible or from rigid material. The grid can be opaque (scattering) or it can be optically transparent, in either case so that there is mixing between grid cells. Alternatively, it can be absorbing or reflecting so that light is essentially contained within grid cells until it escapes.

If a partially transparent material is used, light spreading between adjacent cells and improved colour mixing is obtained.

The light out-coupling structures can be openings, or optical windows. For example, the top reflector foil can comprise a transparent substrate on which is printed a reflector layer, which itself defines the windows. Thus, the openings are provided only in a coating layer not in the complete foil.

The reflecting foil or foils preferably have a nominal reflectivity of above 98%. If a coating such as paint is used instead of a high reflectivity second foil, the output brightness may be lower. For example, the reflectivity of a paint may be around 70%, giving higher absorption losses in the paint.

The invention can be applied with low reflectivity coatings on both sides of the cavity, although the efficiency will be lower. Thus, the surface of the circuit board carrying the lighting elements, and the top reflector are preferably each at least 70% reflective for the visible light spectrum.

Different colour LEDs can be used—for example red, green and blue LEDs in each grid area, or else any desired colour pattern across the surface of the lighting system.

In the examples described, all LEDs are controlled in common. However, the LEDs could be independently controllable, by providing individual connections to the conductor areas 34. This would require a more complicated PCB design, but would enable the light output pattern to be controllable.

The LEDs can be side-emitting so that the light fills the area of the grid cell without requiring multiple reflections. By side emitting is mean that the direction of light output is substantially parallel to the plane of the circuit board on which the LEDs are mounted, for example the light output may be within a range of +−20 degrees to this parallel plane. Side emitting LED modules are well known.

In the examples above, the spacer layer is printed. However, it may be pre-formed (printed or stamped for example), and applied by a lamination process to the printed circuit board.

The invention is applicable to general illumination applications, backlighting, decorative light systems, emissive windows, curtains, blinds and other panels.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage. Any reference signs in the claims should not be construed as limiting the scope.

1. A lighting system comprising:
a circuit board which carries a lighting circuit comprising a plurality of lighting elements, wherein the surface of the circuit board carrying the lighting elements is at least partially reflective;
a spacer layer over the circuit board;
a top reflector over the spacer layer, wherein the spacer layer defines an air gap between the circuit board and the top reflector, wherein the top reflector and/or the circuit board is provided with a light out-coupling structure,
and wherein the circuit board comprises a patterned top conductor which has an array of isolated conductor areas surrounded by a common conductor area, wherein one or more lighting elements are connected between each isolated conductor area and the common conductor area.

2. A lighting system as claimed in claim 1, wherein the surface of the circuit board carrying the lighting elements is provided with a reflective foil.

3. A lighting system as claimed in claim 1, wherein the surface of the circuit board carrying the lighting elements has a paint coating.

4. A lighting system as claimed in claim 1, wherein the spacer layer defines a grid, with the same number of one or more lighting elements associated with each grid opening.

5. A lighting system as claimed in claim 4, wherein the spacer layer is formed of a partially transparent material.

6. A lighting system as claimed in claim 1, wherein the light out-coupling structure comprises an array of holes.

7. A lighting system as claimed in claim 1, wherein the circuit board comprises a bottom conductor on the opposite side of the board, and wherein the system comprises an AC power supply connected between the common conductor area and the bottom conductor.

8. A lighting system as claimed in claim 1, wherein the lighting elements comprise LEDs.

9. A lighting system as claimed in claim 8, wherein the lighting elements comprise side emitting LEDs.

10. A method of manufacturing a lighting system, comprising:
providing a circuit board which carries a lighting circuit comprising a plurality of lighting elements, wherein the surface of the circuit board carrying the lighting elements is at least partially reflective;
providing a spacer layer over the circuit board; and
providing a top reflector over the spacer layer, wherein the spacer layer defines an air gap between the circuit board and the top reflector;
wherein the top reflector and/or the circuit board is provided with a light out-coupling structure,
and wherein the circuit board comprises a patterned top conductor which has an array of isolated conductor areas surrounded by a common conductor area, wherein one or more of the lighting elements are connected between each isolated conductor area and the common conductor area.

11. A method as claimed in claim 10, comprising providing the surface of the circuit board carrying the lighting elements with a reflective foil.

12. A method as claimed in claim 10, comprising providing the surface of the circuit board carrying the lighting elements with a paint coating.

13. A method as claimed in claim 10, wherein the spacer layer is formed by printing.

14. A method as claimed in claim 10, wherein the light out-coupling structure comprises an array of holes.
